(19) United States
(12) Patent Application Publication
(10) Pub. No.: US 2017/0098494 A1
(43) Pub. Date: Apr. 6, 2017

(54) MANUFACTURING A CONDUCTIVE NANOWIRE LAYER

(71) Applicant: M-SOLV LIMITED, Oxford, Oxfordshire (GB)

(72) Inventors: Alan Brian DALTON, Haslemere (GB); Lester Taku SATO, Leighton Buzzard (GB); Matthew LARGE, Guildford (GB); Philip Thomas RUMSBY, Bladon (GB)

(73) Assignee: M-SOLV LIMITED, Oxford, Oxfordshire (GB)

(21) Appl. No.: 15/312,516

(22) PCT Filed: May 11, 2015
(86) PCT No.: PCT/GB2015/051378

§ 371 Date: Nov. 18, 2016

(30) Foreign Application Priority Data
May 20, 2014 (GB) 1408949.4

(51) Int. Cl. H01B 13/00; H01B 1/02; H01B 13/34; H01M 4/88; H01L 31/18; B05D 1/02; B05D 1/26; H01M 4/04; H01B 5/14; H01L 31/0224

(52) U.S. Cl. CPC H01B 13/0026; H01B 5/14; H01B 1/02; H01B 13/34; H01L 31/022491; H01L 31/1884; H01L 31/188; B05D 1/02; B05D 1/265; H01M 4/0419; H01M 4/0411; H01M 4/8864; H01M 4/8828; G06F 3/041

(57) ABSTRACT

Methods and apparatus for manufacturing a conductive thin film are provided. In one arrangement, compositions of nanowires having different mean aspect ratios are mixed together and applied as a layer on a substrate. In other arrangements a single composition of nanowires is processed in order to increase an aspect ratio variance and the processed composition is applied as a layer on a substrate. The layers thus applied provide an improved balance of electrical conductivity to transparency and are expected to provide improved isotropy in the inplane conductivity.

The present invention relates to methods and apparatus for manufacturing a conductive thin film that has high performance in terms of its optical and electrical properties, and low cost. The invention relates in particular to films that are also transparent.

Indium tin oxide (ITO) is one of the most used materials in applications where there is a need for transparent and conductive thin films due to its low sheet resistance, R_{S}, (R_{S}<100 Ω/sq), and high optical transmittance (T>90%). However, ITO suffers from several important drawbacks, such as high cost, brittleness, and a requirement for high processing temperatures.

Silver nanowires (AgNWs) are a potential candidate to replace ITO. High electrical and thermal conductivities, as well as excellent optical transmittance of AgNW networks make them one of the most promising materials to be used as transparent electrodes in optoelectronic applications. Many groups have reported using AgNWs to produce flexible, transparent, and conducting thin films. Polymer substrates coated with thin films of AgNW are available commercially from various suppliers e.g. Toray, Carestream, Okura and Hitachi Chemical.

There are many techniques available to fabricate thin films of AgNWs on substrates, such as vacuum filtration, Langmuir-Blodgett (LB), drop casting, Meyer-rod-coating, spray deposition and slot die coating.

De and co-workers have produced AgNW thin films by vacuum filtering aqueous dispersions of AgNWs onto a cellulose membrane, achieving a transmittance, T, of 85% and a R_{S} of 13 Ω/sq. (van de Groep, J., P. Spinelli, and A. Polman, Transparent Conducting Silver Nanowire Networks. Nano Letters, 2012. 12(6): p. 3138-3144). Hu et al. have reported the use of the Meyer rod coating technique to produce AgNW thin films with T=80% and R_{S}=20 Ω/sq (Hu, L., et al., Scalable Coating and Properties of Transparent, Flexible, Silver Nanowire Electrodes. ACS Nano, 2010. 4: p. 2955-2963). Scardaci et al. have reported large-scale deposition of AgNWs with spray coating. They showed T=90% and R_{S}=50 Ω/sq for their deposited films (Scardaci, V., et al., Spray Deposition of Highly Transparent, Low-Resistance Networks of Silver Nanowires over Large Areas. Small, 2011. 7(18): p. 2621-2628, Scardaci, V., R. Coull, and J. N. Coleman. Spray deposition of Silver Nanowire transparent conductive networks. in Nanotechnology (IEEE-NANO), 2012 12th IEEE Conference on. 2012).

Although AgNW networks demonstrate comparable electrical conductivity and optical transmittance to ITO thin films, some challenges remain. For example, it would be desirable to increase the in-plane electrical conductivity for a given quantity of AgNWs. AgNWs are currently very expensive (˜$5/mg), so reducing the quantity of AgNWs will tend to reduce manufacturing costs. Furthermore, reducing the quantity of AgNWs will help to increase optical transmittance. It would also be desirable to reduce or eliminate anisotropy in the in-plane electrical conductivity.

It is an object of the invention to provide methods and apparatus that allow for improved manufacture of conductive thin films, at least partially addressing one or more of the problems with the prior art discussed above.

According to an aspect of the invention, there is provided a method of manufacturing a conductive thin film, comprising: providing first and second compositions of nanowires, each composition being initially separate from the other; applying the first and second compositions to a substrate in order to form a layer of nanowires on the substrate, the first and second compositions being mixed together before or during the application, wherein: a mean aspect ratio, defined as the mean ratio of the length to the cross-sectional diameter of a nanowire, of the nanowires in the first composition is larger than the mean aspect ratio of the nanowires in the second composition.

According to an alternative aspect of the invention, there is provided a method of manufacturing a conductive thin film, comprising: providing a composition of nanowires in which each nanowire has an aspect ratio defined as the ratio of the length to the cross-sectional diameter of the nanowire; processing the composition of nanowires so as to increase the variance in the distribution of aspect ratios in the composition by a factor of at least 1.5; and applying the composition of nanowires having the increased variance to a substrate in order to form a layer of nanowires on the substrate.

The inventors have found that using the mixture of nanowire compositions, or the nanowire composition that has been treated to increase the aspect ratio variance, provides an improved balance of electrical conductivity to transparency (generally increasing conductivity for a given quantity of nanowires). Additionally, analysis by the inventors shows that the isotropy of the in-plane electrical conductivity should be improved. This makes the approach particularly advantageous where manufacturing methods tend intrinsically to introduce spatial anisotropy into the nanowire layer, which can result in electrical anisotropy. For example, it is known that the slot-die coating process imparts significant shear forces on the nanowires. It is known that this can result in significantly anisotropic in-plane electrical properties. The present invention will tend to reduce or eliminate such anisotropy. The improvement in isotropy is thought to occur because of the tendency for shorter nanowires to be rotated by shear stresses to a lesser extent than longer nanowires. Where a mixture of shorter and longer nanowires are provided (as in the present invention), the longer nanowires will tend to be effective generally for maintaining high electrical conductivity and the shorter nanowires will tend to maintain cross-linking (and therefore percolation) between the longer nanowires even in the presence of shear forces.

According to an alternative aspect of the invention, there is provided an apparatus for manufacturing a conductive thin film, comprising: a first storage device containing a first composition of nanowires; a second storage device containing a second composition of nanowires; an applicator configured to apply the first and second compositions to a substrate in order to form a layer of nanowires on the substrate, the first and second compositions being mixed together before or during the application, wherein: a mean aspect ratio, defined as the mean ratio of the length to the cross-sectional diameter of a nanowire, of the nanowires in the first composition is larger than the mean aspect ratio of the nanowires in the second composition.

According to an alternative aspect of the invention, there is provided an apparatus for manufacturing a conductive thin film, comprising: a storage device containing a composition of nanowires in which each nanowire has an aspect ratio defined as the ratio of the length to the cross-sectional diameter of the nanowire; a nanowire processor configured to process the composition of nanowires so as to increase the variance in the distribution of aspect ratios in the composition by a factor of at least 1.5; an applicator configured to apply the processed composition of nanowires to a substrate in order to form a layer of nanowires on the substrate.

Embodiments of the invention will now be described, by way of example only, with reference to the accompanying drawings in which corresponding reference symbols indicate corresponding parts, and in which:

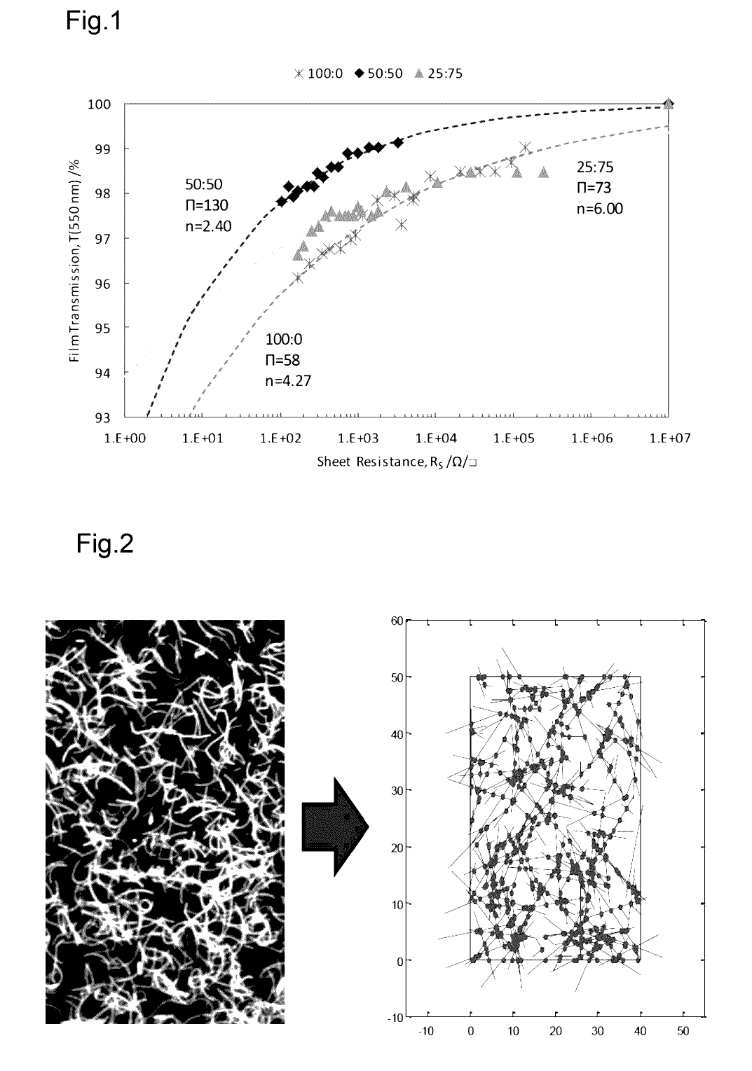

FIG. 1 depicts experimentally determined variations of film transmission against sheet resistance for different compositions of nanowire;

FIG. 2 shows how a mathematical model can be used to simulate the electrical properties of a layer of nanowires;

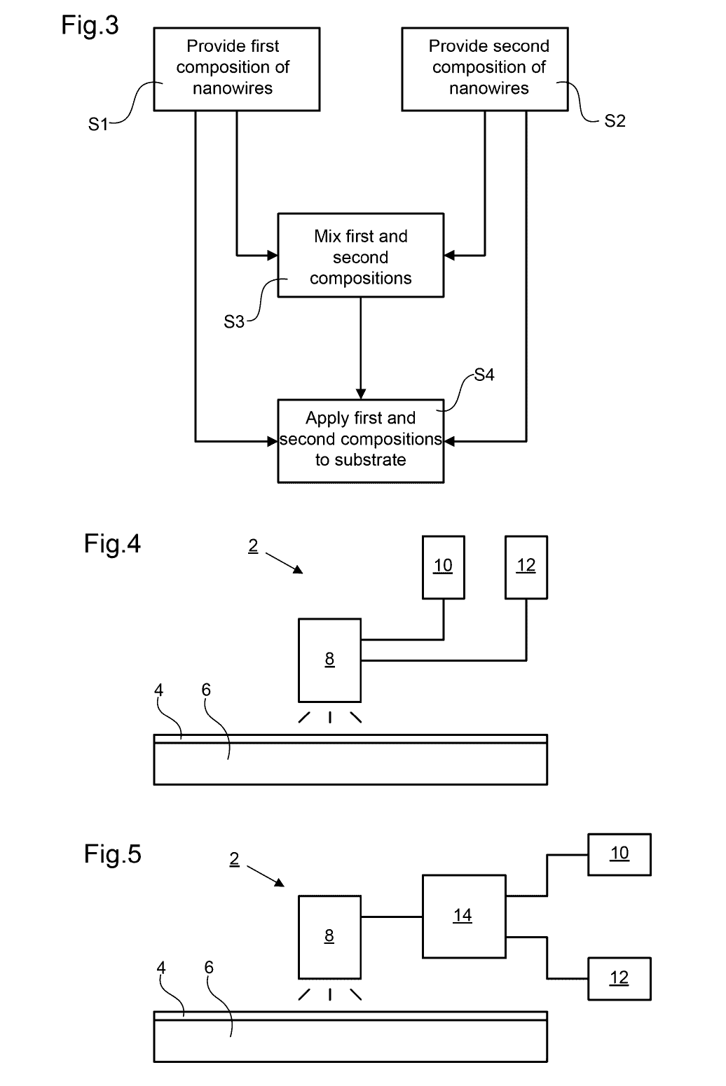

FIG. 3 is a flow chart depicting a method of manufacturing a conductive thin film according to an embodiment;

FIG. 4 depicts an apparatus for manufacturing a conductive thin film according to an embodiment;

FIG. 5 depicts an apparatus for manufacturing a conductive thin film according to an alternative embodiment;

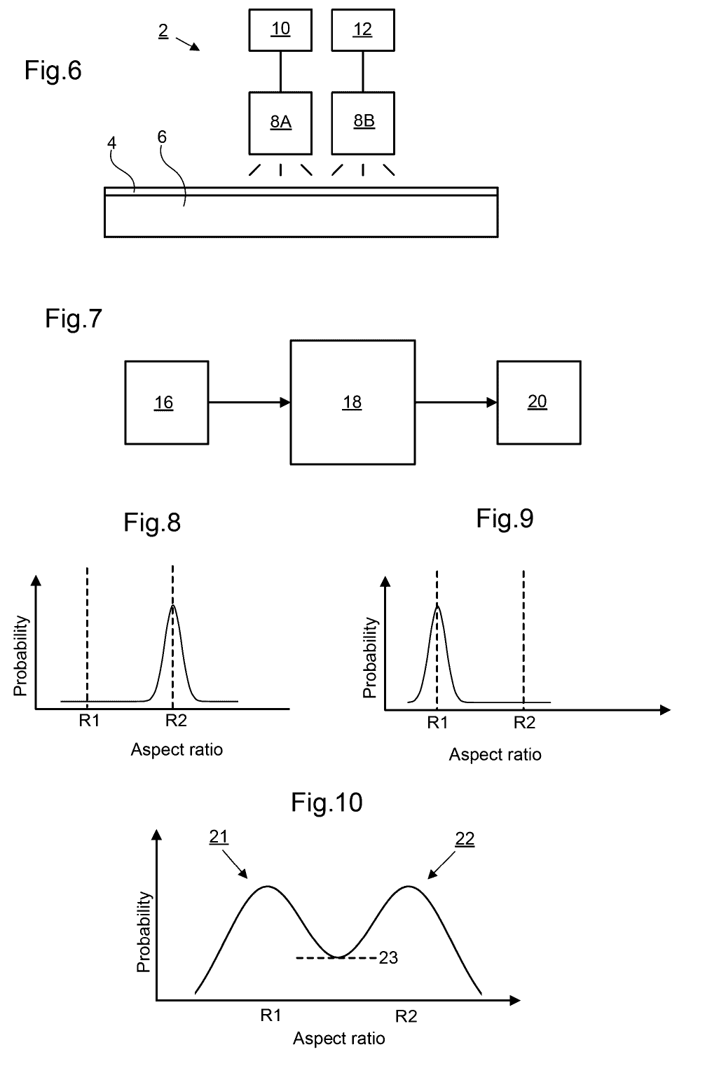

FIG. 6 depicts an apparatus for manufacturing a conductive thin film according to an alternative embodiment in which the applicator is implemented using two separate sub-applicators;

FIG. 7 depicts a nanowire processor for use with an apparatus for manufacturing a conductive thin film;

FIG. 8 depicts a first example nanowire aspect ratio distribution for a composition of nanowires;

FIG. 9 depicts a second example nanowire aspect ratio distribution for a composition of nanowires;

FIG. 10 depicts a nanowire aspect ratio distribution for an example composition resulting from mixing of compositions of the type shown in FIGS. 8 and 9;

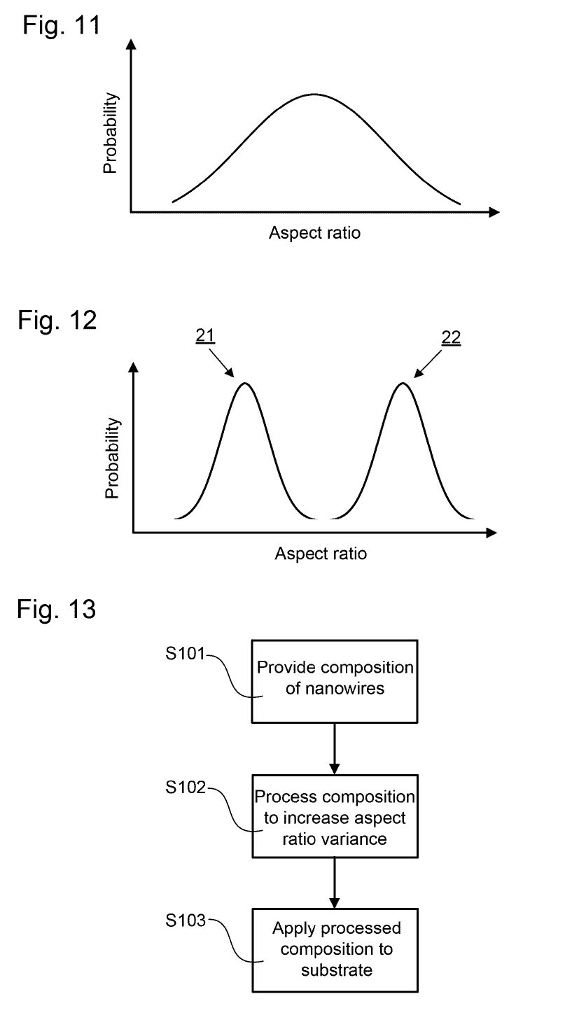

FIG. 11 depicts a nanowire aspect ratio distribution for an alternative composition resulting from a mixing of compositions of the type shown in FIGS. 8 and 9;

FIG. 12 depicts a nanowire aspect ratio distribution for a further alternative composition resulting from a mixing of compositions of the type shown in FIGS. 8 and 9;

FIG. 13 is a flow chart depicting a method of manufacturing a conductive film according to an alternative embodiment;

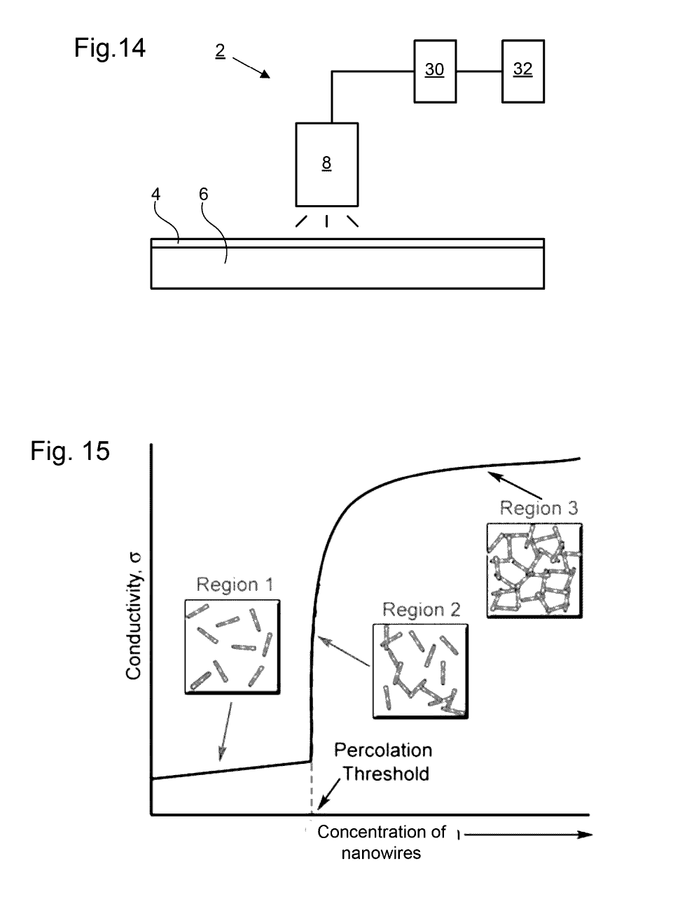

FIG. 14 depicts an apparatus for manufacturing a conductive thin film according to an embodiment in which a composition of nanowires is processed to increase a variance in the aspect ratio of the nanowires;

FIG. 15 depicts the variation of conductivity as a function of concentration for a nanowire layer in and around the percolative regime.

The present inventors have recognised that it is possible to alter the percolating properties of nanowire films by adjusting the aspect ratio distribution (for a given cross-sectional diameter this may be referred to equivalently as the length distribution) of the nanowires.

Transmission-Sheet resistance experiments were carried out and confirmed the idea that variation of the aspect ratio distribution produces a significant effect on the percolative behaviour of nanowire thin films. A bi-modal mixing of longer and shorter nanowires was performed by mixing of unsonicated and sonicated silver nanowire dispersions in different volume ratios. The resulting compositions were sprayed onto a polymer substrate to produce an isotropic film. Example results are depicted in FIG. 1 for three different nanowire compositions. The crosses represent data from a composition formed from longer nanowires only. The diamonds represent data from a composition comprising 50% longer and 50% shorter nanowires. The triangles represent data from a composition comprising 25% longer and 75% shorter. The vertical axis measures film transmission, so higher values are more desirable. The horizontal axis measures sheet resistance, so lower values are more desirable. The best properties therefore correspond to regions towards the upper left portion of the graph. As can be seen, the data points corresponding to the unmixed 100% longer nanowire composition are significantly worse (i.e. more to the right and down) than the data points of both of the two mixed compositions.

The following fitting function can be used to describe the data more formally and has been used to generate the three broken lines in FIG. 11 by fitting to the respective three data sets:

$$T = {100 [ 1 + \frac{1}{Π} {( \frac{{Z}_{0}}{{R}_{S}} )}^{\frac{1}{1 + n}} ]}^{- 2} .$$

Here T is the optical transmission of the film at 550 nm; Π is the percolative figure of merit; Z₀ is the impedance of free space (377Ω); R_{S} is the sheet resistance of the film; n is the percolative exponent for the electrical properties of the film. Superior films are characterised by larger values of Π; this constitutes the coupling of high optical transmission and low sheet resistance. As shown in FIG. 1, mixing of different length ratios (long:short) of nanowires has a significant positive impact on the behaviour of the film.

Theory suggests that Π should be related to the length distribution (and therefore, equivalently, the aspect ratio distribution) of the particles forming the film as follows:

$$Π = A [ \frac{( {〈 l 〉}^{2} + {σ}^{2} )}{〈 l 〉 {d}_{NW}} ] ,$$

where A is a constant for the materials used; <l> is the mean nanowire length; σ² is the variance in the nanowire length; d_{NW} is the nominal diameter of the nanowires. This expression shows that nanowires with smaller diameter and larger mean length will produce superior films by increasing Π. The present inventors have also recognised that increasing the variance in the length (or aspect ratio) distribution can also be used to improves the film properties.

The inventors have performed simulations of nanowire networks using a Monte-Carlo process. A list of nanowires is generated which have an isotropic arrangement on a 2-dimensional domain, and an isotropic orientational arrangement. The distribution of aspect ratios can be tailored to an arbitrary distribution, by using the appropriate cumulative probability density (CPD) function. The distribution of nanowires is illustrated schematically in FIG. 2 (left). The intersections of the nanowires are then determined (as shown in FIG. 2 (right)). The determined intersections are used to construct the Laplacian matrix for the graph of the connected network. A result from the field of Graph Theory allows calculation of the resistance of the network between any two points based on the generalised inverse of the Laplacian matrix.

This process allows the resistance of layers formed by arbitrary distributions of nanowires to be predicted by simulation. Based on such simulations the inventors have confirmed that increasing the variance in aspect ratio significantly reduces the sheet resistance for a given density of nanowires. The model can also be used to simulate how the electrical properties of the network behave as the size or shape of the domain containing the nanowires (i.e. the size and/or shape of the layer of nanowires being simulated) changes. For example, the model can be used to predict how narrow tracks of nanowire film will behave. Such narrow tracks often need to be formed in commercial applications, for example in capacitive touch sensors or LCD pixel electrodes. The inventors have shown that tailoring the aspect ratio distribution can reduce the rate of track failure at small track widths, which is a strong advantage.

It is understood that some methods of depositing nanowire films introduce large anisotropy into the resulting electrical properties. For example, slot die coating used in current commercial film production can produce perpendicular resistances of near 1.5 times that in the parallel direction. This is a result of the shear forces in the nanowire solution as it is dragged through the slot die; torque is applied to the nanowires causing them to align. Since the torque applied scales with nanowire length (and therefore aspect ratio) it is possible to reduce this electrical anisotropy by tailoring the nanowire length distribution; shorter nanowires will align less, and therefore bridge between longer nanowires in the perpendicular direction. This in turn will reduce the anisotropic effect in the sheet conductivity.

In an embodiment, a method of manufacturing a conductive thin film is provided. FIG. 3 is a flowchart describing an example framework for such a method.

The method comprises providing first and second compositions of nanowires (steps S1 and S2). Each composition is initially separate from the other (e.g. such that there is no mixing between the two compositions).

In a subsequent step, step S3 and/or step S4, the first and second compositions are applied to a substrate in order to form a layer of nanowires on the substrate. The first and second compositions may be mixed together before the application or during the application. The first and second compositions may be applied to the substrate simultaneously or one after the other (sequentially). In the case where the first and second compositions are applied to a given portion of the substrate at different times, the mixing together of the first and second compositions may occur as the later applied composition is applied. The mixing may be partial and/or inhomogeneous mixing. For example, in the case where the first composition is applied first and the second composition applied afterwards, on top of the first composition, a greater degree of mixing may occur at the upper surface of the first composition where the first and second compositions are first brought into contact than at the lower extremity of the applied first composition, for example.

An example apparatus 2 for manufacturing a conductive thin film is shown schematically in FIG. 4. The apparatus 2 comprises a first storage device 10 containing the first composition of nanowires and a second storage device 12 containing the second composition of nanowires. The apparatus 2 further comprises an applicator 8 configured to apply the first and second compositions to a substrate 6 in order to form a layer 4 of nanowires on the substrate 6. The apparatus 2 may be configured such that the first and second compositions are mixed together before or during the application. The first and second compositions may be applied to the substrate simultaneously or one after the other (sequentially). The applicator may be a single applicator or may comprise a plurality of applicators (which may be referred to as sub-applicators).

In the embodiment of FIG. 4, the first and second compositions are provided to the applicator 8 from different, separate storage devices 10 and 12. However, this is not essential. FIG. 5 depicts an alternative arrangement in which the apparatus 2 for manufacturing a conductive thin film comprises a storage device 14 that contains a mixture of the first and second compositions. The first and second compositions may be provided to the storage device 14 from separate storage devices 10 and 12.

In the arrangements of FIGS. 4 and 5 a single applicator 8 is provided for applying the first and second compositions. However, this is not essential. In other embodiments the applicator may comprise a plurality of sub-applicators (such an arrangement may also be referred to as a plurality of applicators). An example of such an arrangement is shown in FIG. 6. Here, the first and second compositions are provided respectively to two different sub-applicators 8A and 8B from two different storage devices 10 and 12. The sub-applicators 8A and 8B may apply the first and second compositions simultaneously or sequentially (one after the other).

The applicator 8 or sub-applicators 8A, 8B may be moved/scanned relative to the substrate 6 (either by moving the applicators/sub-applicators or by moving the substrate).

Each nanowire in the compositions has an aspect ratio defined as the ratio of the length of the nanowire to the cross-sectional diameter of the nanowire (or mean or maximal cross-sectional diameter where the cross-sectional diameter varies significantly along the length of the nanowire). It is understood that the cross-sectional diameter is a cross-sectional diameter perpendicular to a longitudinal axis of the nanowire. Typically, the cross-section takes a circular or approximately circular form and the diameter is the diameter of that circle or average diameter when the diameter varies as a function of angle within the cross-section. The distribution of nanowire shapes and sizes in the compositions may be characterized by reference to the mean aspect ratio of the nanowires contained in the compositions. In an embodiment, the first and second compositions are formulated such that the mean aspect ratio is larger in the first composition than in the second composition.

In an embodiment the first composition is a typical, commercially available composition having nanowires of a relatively uniform size and shape (and therefore aspect ratio). The distribution of aspect ratios in the first composition may therefore be described by a curve of concentration against aspect ratio that is sharply peaked around the mean aspect ratio. An example distribution for the first composition is illustrated schematically in FIG. 8, with the mean aspect ratio marked as R2.

In an embodiment the second composition is a typical, commercially available composition having nanowires of relatively uniform size and shape (and therefore aspect ratio). Alternatively, the second composition may be obtained by processing a third composition of nanowires (which may itself be a typical, commercially available composition having nanowires of relatively uniform size and shape, for example). For example, as shown in FIG. 7, the apparatus may comprise a nanowire processor 18 that is configured to process the third composition of nanowires (stored in a storage device 16) in order to reduce the mean aspect ratio of the nanowires in the third composition of nanowires. The output nanowires of reduced mean aspect ratio may be stored in a storage device 20. The nanowire processor 18 may reduce the mean aspect ratio of the nanowires by subjecting them to sonication that is suitable to break at least a subset of them into smaller pieces for example. In the example of FIG. 7 the sonication is conducted using a standalone unit and/or offline. However, this is not essential. In other embodiments, the sonication could be carried out as an inline process. For example, in arrangements such as those shown in FIGS. 4-6, a sonication device could be incorporated into either or both of the storage devices 10 and 12 or in conduits leading from the storage devices to the applicator 8. The sonication device could be a tip sonicator in the storage device or a flow cell sonicator capable of recirculating the compositions. A single storage device could be provided with a plurality of output conduits each having a differently configured (or no) sonication device associated with it. In this way, a given composition of nanowires can be split into two or more compositions (one for each output conduit) having different properties from each other caused by applying different (or no) sonication processing to the different output conduits.

FIGS. 8 and 9 are schematic graphs showing a distribution of aspect ratios respectively for the first and second compositions. The distribution for the first composition peaks at a mean aspect ratio of R2. The distribution for the second composition peaks at a lower mean value of R1. The distribution of aspect ratios that is obtained when the first and second compositions are mixed together will depend on the relative amounts of the first and second compositions in the mixture as well as the distributions of aspect ratios present in the first and second compositions. The mixing will increase the range of aspect ratios that are present (i.e. tending to increase the variance in the aspect ratio for example). Various different forms may arise. Three examples of distributions of aspect ratio obtained by mixing first and second compositions having different properties or in different ratios are depicts in FIGS. 10-12.

In FIGS. 10 and 12 distributions having two distinct maxima 21 and 22 are shown. Maxima 21 may be located approximately at the peak aspect ratio R1 of the second composition of FIG. 9. Maxima 22 may be located approximately at the peak aspect ratio R2 of the first composition of FIG. 8. In FIG. 10, the distribution falls to an intermediate value 23 in between the two peaks 21 and 22, the intermediate value being lower than the maxima values but substantially higher than zero. In FIG. 12, the distribution falls to substantially zero in between the two maxima 21 and 22.

In FIG. 11 the distribution is broader (i.e. has higher variance) than the distributions of the first and second compositions but does not have two distinct maxima. In other embodiments, the distribution may have more than two maxima. This may be achieved for example by mixing together first and second compositions as described above, together with one or more further compositions each having different mean aspect ratios in comparison to the first and second compositions.

In the examples of FIGS. 10-12, the graphs all show 1:1 mixing. However, this is not essential. In other arrangements other mixing ratios may be used, for example 1:10, 1:4, etc.

In the embodiments discussed above a composition of nanowires having a range of nanowire lengths is created by a method comprising mixing together two distinct compositions, either before or during application of the nanowires to the surface of a substrate. However, it is not essential that the composition of nanowires be created in this way. The nanowire processor 18 for example may be configured to take as input a distribution of nanowires having a small variance (e.g. a distribution having a narrow peak as shown in FIG. 8 or FIG. 9 for example) and process it so that the variance increases.

Regardless of how the distribution of nanowires in the nanowire layer is created, performance that is significantly superior to typical, commercially available nanowire distributions can be achieved if the variance in the aspect ratio of the nanowires is increased by a factor of 1.5 or more, preferably 2 or more, preferably 5 or more, preferably 10 or more, preferably 50 or more. The variance in the aspect ratio can be achieved by mixing together different compositions of nanowires, as described above with reference to FIGS. 3-12. However, the increase in variance can also be achieved by operating directly on a given composition of nanowires. For example, sonication can be used to increase the variance in aspect ratio of a composition of nanowires.

FIG. 13 is a flow chart describing an example framework for such a method. The method comprises providing a composition of nanowires S101 in which each nanowire has an aspect ratio defined as the ratio of the length to the cross-sectional diameter of the nanowire. The composition of nanowires S101 provided in step S101 is then processed so as to increase the variance in the distribution of aspect ratios in the composition by a factor of 1.5 or more, preferably 2 or more, preferably 5 or more, preferably 10 or more, preferably 50. In step S103, the composition of nanowires having the increased variance is applied to a substrate in order to form a layer of nanowires on the substrate. FIG. 14 depicts an example apparatus for carrying out such a method. A storage device 32 is provided for containing an initial composition of nanowires. A nanowire processor 30 is provided that processes nanowires from the storage device so as to increase the variance in the distribution of aspect ratios of the nanowires. An applicator 8 is provided that applies the nanowires treated by the nanowire processor 30 to a substrate 6 in order to form a layer 4 of nanowires on the substrate 6.

The above methods and apparatus are particularly effective where the layer of nanowires is deposited at a density that causes the optical and/or electrical properties of the film to exhibit percolative behaviour to a greater extent than bulk behaviour. The nanowire layer 4 thus formed may or may not be a monolayer. A characteristic feature of the percolative regime is that the following power law relationship is satisfied between the conductivity of the layer and the concentration of the nanowires within the layer:

σ=σ₀(φ−φ_{c})^{t}

for

φ>φ_{c}

where σ is the conductivity of the nanowire layer (S/cm), σ₀ is a proportionality constant, and φ is the concentration of nanowires in the layer, φ_{c} is the critical concentration marking the lower bound of the percolative behaviour, and t is a power law exponent in the range of 1-1.33.

The behaviour of percolative networks can be described using percolation theory (Stauffer, D., Introduction to percolation theory. Taylor & Francis: London; Philadelphia, 1985, Kulshreshtha, A. K.; Vasile, C., Handbook of polymer blends and composites. Rapra Technology Lt.: Shawbury, Shewsbury, Shropshire, [England], 2002). FIG. 15 is a schematic illustration, based on this theory, showing the expected variation in conductivity as a function of nanowire concentration. As can be seen, below a critical concentration of the nanowires (φ_{c}), the overall conductivity approaches zero (Region 1 in FIG. 15), with individual wires largely disconnected from each other (see inset). At a critical concentration of the nanowires, φ_{c}, an insulator-conductor transition takes place, marking the point at which continuous paths start to be formed along lines of nanowires. In a narrow regime just beyond φ_{c} the conductivity rises very quickly as the continuous networks are formed (Region 2 in FIG. 15; see inset). At higher concentrations, once a conductive network has been fully formed (Region 3 in FIG. 15 and associated insert), the rate of rise of conductivity is more moderate or even approaches zero as the effect of each additional nanowire on the conductivity falls.

In a specific example in which the metal nanowires are AgNWs, the nanowires are provided at a density which causes the sheet resistance R_{S} of the metal nanowires to be equal to or greater than 100 Ω/sq, preferably equal to or greater than 10³ Ω/sq, preferably equal to or greater than 10⁴ Ω/sq, preferably equal to or greater than 10⁵ Ω/sq, preferably equal to or greater than 10⁶ Ω/sq, preferably equal to or greater than 10⁷ Ω/sq, preferably equal to or greater than 10⁸ Ω/sq, preferably equal to or greater than 10 ⁹ Ω/sq, preferably equal to or greater than 10¹⁰ Ω/sq, preferably equal to or greater than 10¹¹ Ω/sq, preferably equal to or greater than 10¹² Ω/sq. Embodiments of the invention may also be applied where the sheet resistance takes lower values, for example lower than 100 Ω/sq.

The substrate may be transparent, for example where the thin film is to be used to implement a touch screen display. Alternatively, the substrate may be opaque, which may be acceptable where the thin film is to be used in batteries or fuel cells, for example.

The metal nanowires may be formed from one or more of a range of different metals, including one or more of the following: Ag, Au, Pt, Cu, Pd, Ti, Al, Li.

In an embodiment, the applying of the nanowires S4 or S103 on the substrate 6 by the applicator 8 is performed by spray deposition. Alternatively or additionally, the applying of the nanowires S4 or S103 on the substrate 6 by the applicator 8 is performed by slot die coating. Both of these methods have a tendency to produce an anisotropic spatial distribution of the nanowires on the substrate (generally to a greater extent in slot die coating than in spray deposition). The anisotropic spatial distribution may lead to anisotropic electrical properties (e.g. greater resistance parallel to a first direction in the plane of the layer than in a second direction perpendicular to the first direction), which are undesirable. In spray deposition, the anisotropy may arise due to non-uniform evaporation of the solvent (leaving so-called “tide marks” for example in the spatial distribution of the nanowires). In slot-die coating it is well known that significant shear forces are applied to the nanowires and anisotropic electrical properties arising due to this have been observed in practice. Embodiments of the present invention are particularly advantageous in the context of methods of application such as these because the distribution of nanowires is more resistant to shear forces and/or other effects that tend to cause electrical anisotropy because the wide variance of aspect ratios ensures that longer (higher aspect ratio) nanowires are present to enhance conductivity generally while shorter (lower aspect ratio) nanowires, which tend to be aligned with each other less by effects such as shear forces and can therefore cross-link between different ones of the longer nanowires and maintain percolation, are also present.

Methods and apparatus according to embodiments may be applied to manufacturing a wide range of devices comprising conductive thin films, for example touch screen panels, photovoltaic panels, and batteries or fuel cells comprising conductive thin films.

1. A method of manufacturing a conductive thin film, comprising:
providing a composition of nanowires in which each nanowire has an aspect ratio defined as the ratio of the length to the cross-sectional diameter of the nanowire;
processing the composition of nanowires so as to increase the variance in the distribution of aspect ratios in the composition by a factor of at least 1.5; and
applying the composition of nanowires having the increased variance to a substrate in order to form a layer of nanowires on the substrate.

2. A method of manufacturing a conductive thin film, comprising:
providing first and second compositions of nanowires, each composition being initially separate from the other;
applying the first and second compositions to a substrate in order to form a layer of nanowires on the substrate, the first and second compositions being mixed together before or during the application, wherein:
a mean aspect ratio, defined as the mean ratio of the length to the cross-sectional diameter of a nanowire, of the nanowires in the first composition is larger than the mean aspect ratio of the nanowires in the second composition.

3. The method according to claim 2, wherein the distribution of the aspect ratios in the first and second compositions after they have been mixed together has at least two distinct maxima.

4. The method according to claim 2, wherein the first composition comprises an unsonicated dispersion of nanowires and the second composition comprises a sonicated dispersion of nanowires.

5. The method according to claim 1, wherein the layer of nanowires is deposited at a density that causes the optical and/or electrical properties of the film to exhibit percolative behaviour to a greater extent than bulk behaviour.

6. The method according to claim 5, wherein percolative behaviour is characterized by satisfaction of the following power law:
σ=σ₀(φ−φ_{c})^{t}
for
φ>φ_{c}
where σ is the conductivity of the nanowire layer (S/cm), σ₀ is a proportionality constant, and φ is the concentration of nanowires in the layer, φ_{c} is the critical concentration marking the lower bound of the percolative behavior, and t is a power law exponent in the range of 1-1.33.

7. The method according to claim 1, wherein the applying of the nanowires to the substrate is performed by spray deposition.

8. The method according to claim 1, wherein the applying of the nanowires to the substrate is performed by slot-die coating.

9. An apparatus for manufacturing a conductive thin film, comprising:
a storage device containing a composition of nanowires in which each nanowire has an aspect ratio defined as the ratio of the length to the cross-sectional diameter of the nanowire;
a nanowire processor configured to process the composition of nanowires so as to increase the variance in the distribution of aspect ratios in the composition by a factor of at least 1.5;
an applicator configured to apply the processed composition of nanowires to a substrate in order to form a layer of nanowires on the substrate.

10. An apparatus for manufacturing a conductive thin film, comprising:
a first storage device containing a first composition of nanowires;
a second storage device containing a second composition of nanowires;
an applicator configured to apply the first and second compositions to a substrate in order to form a layer of nanowires on the substrate, the first and second compositions being mixed together before or during the application, wherein:
a mean aspect ratio, defined as the mean ratio of the length to the cross-sectional diameter of a nanowire, of the nanowires in the first composition is larger than the mean aspect ratio of the nanowires in the second composition.

11. The apparatus according to claim 10, further comprising a nanowire processor configured to provide the second composition of nanowires by processing a third composition of nanowires in order to reduce the mean aspect ratio of the nanowires in the third composition of nanowires.

12. The apparatus according to claim 11, wherein the nanowire processor is configured to use sonication to reduce the mean aspect ratio.

13. The apparatus according to claim 9, wherein the applicator is configured to deposit the layer of nanowires at a density that causes the optical and/or electrical properties of the film to exhibit percolative behaviour to a greater extent than bulk behaviour

14. The method according to claim 1, wherein the nanowires comprise one or more of the following: Ag, Au, Pt, Cu, Pd, Ti, Al, Li.

15. The method according to claim 1, wherein the substrate is transparent.

16. The touch screen panel, photovoltaic panel, battery or fuel cell comprising a conductive thin film manufactured according to the method of claim 1.

17. (canceled)

18. (canceled)
